(19) United States
(12) Patent Application Publication
(10) Pub. No.: US 2010/0301333 A1
(43) Pub. Date: Dec. 2, 2010

(54) SEMICONDUCTOR DEVICE AND METHOD OF INSPECTING AN ELECTRICAL CHARACTERISTIC OF A SEMICONDUCTOR DEVICE

(75) Inventor: Kenji KANETA, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/787,815

(22) Filed: May 26, 2010

(30) Foreign Application Priority Data
May 27, 2009 (JP) 2009-127903

(51) Int. Cl. H01L 23/544; G01R 31/26

(52) U.S. Cl. 257/48; 324/765; 257/E23.179

(57) ABSTRACT

A semiconductor device is provided with an electrode pad; and a lower layer arranged under the electrode pad. The electrode pad includes a slit section, penetrating a whole thickness of the electrode pad from a higher surface to a lower surface in contact with the lower layer; a contact start region, arranged in the higher surface, on which a probe makes a contact; and an inspection region, arranged in the higher surface, on which the probe makes an inspection upon the semiconductor. The slit section includes a first group of aperture open to the inspection region; a second group of aperture open to the contact start region smaller than the first group of aperture; and a vacant region able to store a part of shavings produced by the probe while shifting from the contact start region to the inspection region, by grinding the higher surface of the electrode pad.

### INCORPORATION BY REFERENCE

This application claims the benefit of priority based on Japanese Patent Application No. 2009-127903, filed on May 27, 2009, the disclosure of which is incorporated herein by reference.

### BACKGROUND OF THE INVENTION

1. Field of the Invention

The present invention relates to a semiconductor device and to method of inspecting an electrical characteristic of a semiconductor device, and more specifically to an electrode pad for use in wire bonding.

2. Description of Related Art

Wire bonding is one of methods of connecting a semiconductor chip and an external device. The wire bonding is a method of connecting an electrode pad of the semiconductor chip and a substrate with a bonding wire. In order to improve reliability of the semiconductor device, the bonding wire needs to be joined with the electrode pad in one hand and the substrate in the other hand, both with sufficient strength.

A technique related to a semiconductor device having a bonding pad with great adhesiveness is disclosed in Japanese Patent Application JP2003-243443A. This semiconductor device is characterized in that the bonding pad is formed on a flat surface and that a recess portion is formed in a connection region of the bonding pad where a bonding wire is connected. FIG. 1 is a plan view of a bonding pad 100 in the semiconductor device described in Japanese Patent Application JP2003-243443A. Referring to FIG. 1, the bonding pad 100 has a plurality of recess portions 101 formed on a surface with which a ball at a tip of a gold wire is to be joined. Each of the plurality of recess portions 101 is a hole penetrating from a top surface of the bonding pad 100 to a bottom surface thereof, and is a groove-like slit extending in a predetermined direction. Such the bonding pad 100 can effectively form, with the plurality of recess portions 101, a mutual dispersion region at a joining interface with the ball of the gold wire, which can provide favorable adhesion with the ball of the gold wire. Japanese Patent Application JP2003-243443A discloses another embodiment related to the recess portion 101. FIG. 2 is a plan view of the bonding pad 100 of another embodiment in the semiconductor device described in Japanese Patent Application JP2003-243443A. Referring to FIG. 2, another embodiment of the bonding pad 100 of Japanese Patent Application JP2003-243443A has a recess portion 101 shaped into a circular groove. Such a bonding pad 100 has the recess portion 101 formed in an outer peripheral region where the ball of the gold wire is easily press-fit, and thus a mutual dispersion region is easily formed in the outer peripheral region.

### SUMMARY OF THE INVENTION

A semiconductor chip with an element and a wiring formed on a silicon wafer needs to be electrically tested whether a circuit formed on the semiconductor chip properly operates or not, to thereby determine whether the semiconductor is non-defective or defective. An electrical characteristic of the semiconductor chip is tested by using a probe card (for example, a cantilever type card) having a plurality of metal probes, and by making contact between the metal probes and electrode pads (PAD) of the semiconductor chip. During probing, a tip of the probe makes contact with a PAD surface, and the probe in contact with the PAD surface shifts on the PAD surface whereby the PAD surface may be shaved. The inventor of the present invention has found a problem that a presence of shavings on the PAD surface and of a shaving pile formed of shavings of the PAD collected by a tip portion of the probe causes defection in adhesion between the PAD and the bonding wire.

A semiconductor device of the present invention can improve adhesion between a PAD and a bonding wire even when a PAD surface is shaved by probing.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view of a bonding pad 100 in a semiconductor device described in Japanese Patent Application JP2003-243443A;

FIG. 2 is a plan view of a bonding pad 100 of another embodiment in the semiconductor device described in Japanese Patent Application JP2003-243443A;

FIG. 3 is a plan view of a semiconductor device 1 according to a first embodiment of the present invention;

FIG. 4 is a plan view of a PAD 10 shown by letter A of FIG. 3;

FIG. 5A is a sectional view of the PAD 10 shown in FIG. 4, taken along line A-A′;

FIG. 5B is a sectional view of the PAD 10 shown in FIG. 4, taken along line B-B′;

FIG. 6 is a plan view of the PAD 10 after probing;

FIG. 7 is a diagram showing a cross section of a PAD 10 and a probe 40 shifting on the PAD 10 surface during the probing;

FIG. 8 is a flow chart showing a method of inspecting an electrical characteristic of the semiconductor device 1 of the first embodiment of the present invention with a probe card;

FIG. 9 is a plan view of a PAD 10 of a semiconductor device 1 according to a second embodiment of the present invention;

FIG. 10A is a sectional view of the PAD 10 shown in FIG. 9, taken along line D-D′; and

FIG. 10B is a sectional view of the PAD 10 shown in FIG. 9, taken along line E-E′.

### DESCRIPTION OF PREFERRED EMBODIMENTS

Hereinafter, a semiconductor device 1 according to embodiments of the present invention will be described referring to the accompanying drawings.

### First Embodiment

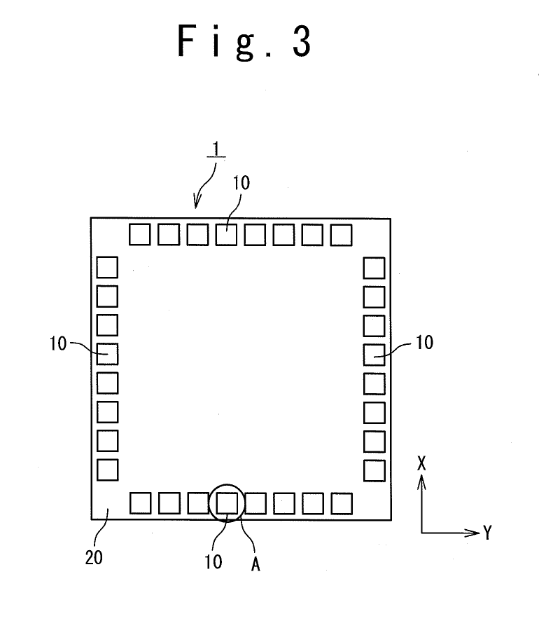

A first embodiment of the present invention will be described. FIG. 3 is a plan view of the semiconductor device 1 according to the first embodiment of the present invention. Referring to FIG. 3, the semiconductor device 1 includes a plurality of PADs 10. Each of the PADs 10 is an electrode pad for connecting together an internal circuit of the semiconductor device 1 and an external device and is a region to which a bonding wire is connected. Before the semiconductor device 1 is connected to the bonding wire, an electrical characteristic of the internal circuit of the semiconductor device 1 is inspected by use of a probe card having a plurality of probes, and this inspection is performed via each of the PAD 10. The semiconductor device 1 has the plurality of PADs 10 along an outer peripheral portion at four sides thereof, although the number and positions of PADs 10 are not limited thereto. To inspect the electrical characteristic of the semiconductor device 1, in order that each of the probes and its corresponding PAD 10 reliably make contact with each other, the probe card in contact with each PAD 10 is pressed from outside in a direction in which each probe and its corresponding PAD 10 approach each other (contact direction) and then each probe shifts on a surface of the PAD 10. In a case where the PADs 10 are provided at the four sides of the semiconductor device 1 as shown in FIG. 3, as a preferable configuration of the probe card, a direction in which each probe shifts on the PAD 10 is a direction from an outer periphery toward a center of the semiconductor device 1, but this direction may be a direction from the center toward the outer periphery. In a case where the semiconductor device 1 does not have PADs 10 at its outer peripheral portion, for example, in a case where it includes the PADs 10 at its central portion, it is preferable that the probes shift on the PADs 10 in a direction from the center toward the outer periphery of the semiconductor device 1.

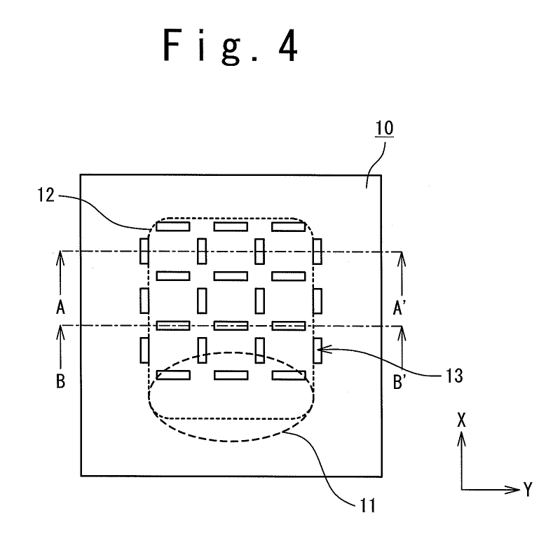

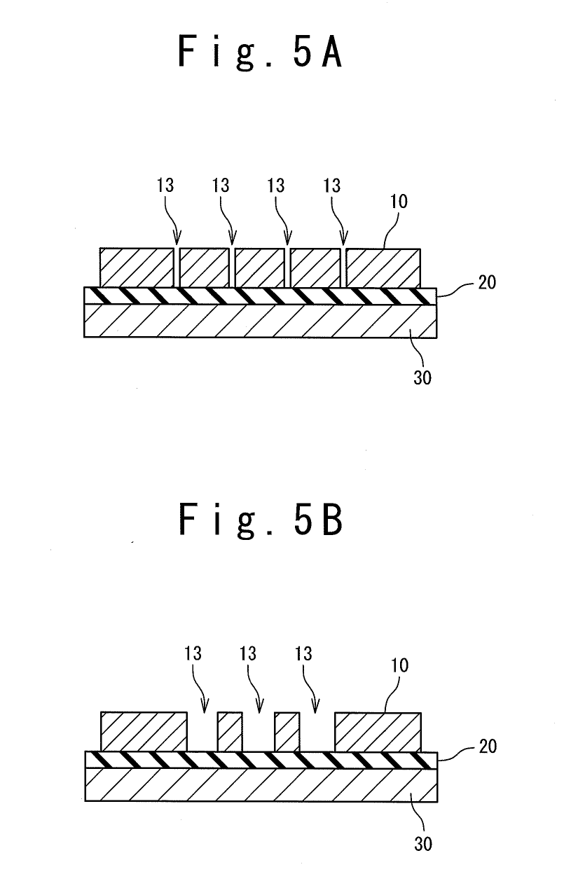

FIG. 4 is a plan view of the PAD 10 shown by letter A of FIG. 3. FIG. 5A is a sectional view of the PAD 10 shown in FIG. 4, taken along line A-A′. FIG. 5B is a sectional view of the PAD 10 shown in FIG. 4, taken along line B-B′. FIGS. 4, 5A, and 5B show states before the inspection performed with the probes of the probe card. Referring to FIGS. 4, 5A, and 5B, the PAD 10 is formed on a lower layer including an insulation film 20 covering a semiconductor substrate 30. The PAD 10 is formed of, for example, a conductive material such as aluminum, and is electrically connected to the internal circuit. The PAD 10 includes a slit section. In this embodiment, the slit section includes a plurality of slits 13.

Each of the plurality of slits 13 is a hole vertically penetrating a whole thickness of the PAD 10 from the higher surface to the lower surface in contact with the insulation film 20. Each of the plurality of slits 13 is arranged on the PAD 10, in view of a position contacted by the probe and the direction in which the probe shifts. More specifically, the plurality of slits 13 are included in a contact start region 11 located outwardly of a center of the PAD 10 surface and an inspection region 12 so located as to include the center of the PAD 10 surface. Then group of aperture of the plurality of slits 13 included in the contact start region 11 is smaller than group of aperture of the plurality of slits 13 included in the inspection region 12.

The contact start region 11 and the inspection region 12 where the plurality of slits 13 are arranged will be described. The contact start region 11 is located outwardly of the center of the PAD 10 surface and is a region with which the probe makes first contact upon the inspection of the electrical characteristic of the semiconductor device 1. The contact start region 11 absorbs impact generated upon the contact made by the probe to thereby protect the semiconductor substrate 30 and the insulation film 20 from the impact of the contact made by the probe. Therefore, in order to permit the absorption of the impact generated upon the contact made by the probe, it is preferable that the group of the aperture of the plurality of slits 13 arranged in the contact start region 11 be small.

The inspection region 12 is a region where the probe in contact with the contact start region 11 shifts from an outer side of the semiconductor device 1 to an inner side thereof (in an X direction here) based on a force of pressure between the probe and the PAD 10 upon the inspection. With the probe electrically connected to the PAD 10 in the inspection region 12, the electrical characteristic is inspected.

It is preferable that the group of the aperture of each of the slits 13 be smaller than a thickness of the probe. In a case where a shape of each slit 13 is rectangular, its size is, for example, 3 to 5 μm for short sides and 10 μm for long sides. The shape of the slit 13 is not limited to a rectangle, but may be circular shape including an oval or any other polygonal shape such as triangular shape. Each slit 13 permits an improvement in adhesion between the PAD 10 after probing and the bonding wire, and thus the adhesion improvement achieved by each slit 13 will be hereinafter described in detail.

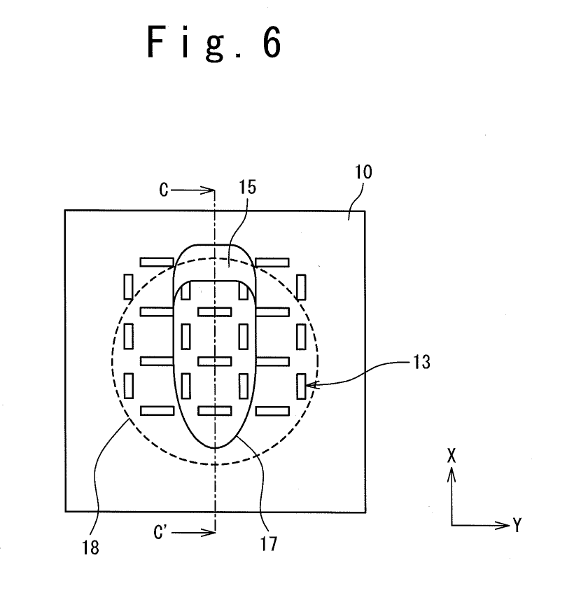

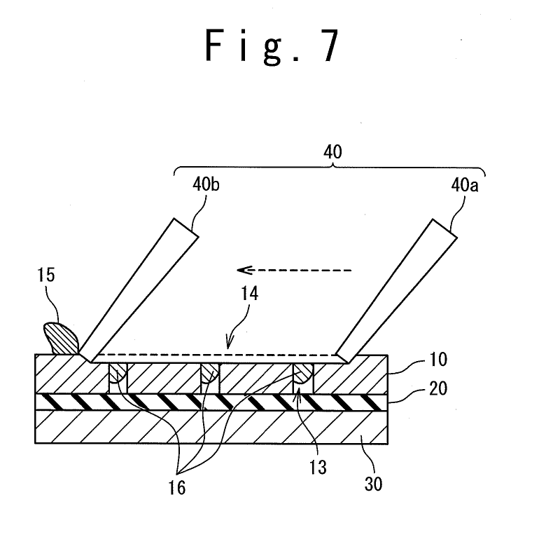

FIG. 6 is a plan view of the PAD 10 after the probing. FIG. 7 is a diagram showing a cross section of a PAD 10 and a probe 40 shifting on the PAD 10 surface during the probing. FIG. 7 corresponds to a cross section taken along line C-C′ of FIG. 6. FIG. 7 shows that the probe 40 at a position 40a in contact with the contact start region 11 shifts to a position 40b of the inspection region 12 based on the pressing force added upon the inspection of the electrical characteristic. At this point, the probe 40 of 10 to 20 μm in thickness shifts while shaving a region 14 of the PAD 10 surface and finally forms a shaving pile 15 at its tip portion at the position 40b. Shavings produced on the PAD 10 surface and the shaving pile 15 become a factor deteriorating the adhesion with the bonding wire; therefore, it is preferable that the shavings formed on the surface be little and the shaving pile 15 be also small. Since the semiconductor device 1 of the present invention includes the plurality of slits 13 open to the PAD 10 surface, a part of the shavings produced from the PAD 10 surface, the shavings 16, is moved by the shifting probe 40 and is stored in the plurality of slits 13, so as to reduce the shavings remaining on the PAD 10 surface. Further, the plurality of slits 13, which penetrates the PAD 10, are vacant region and so contain no conductive material necessary to produce shavings, and the presence of the plurality of slits 13 can reduce the amount of shavings produced. That is, each slit 13 has an advantage of reducing the amount of shavings produced, an advantage of storing the shavings 16 as a part of the shavings produced from the PAD 10 surface to thereby reduce the shavings remaining on the surface, and an advantage of reducing the shaving pile 15. In this manner, the semiconductor device 1 of the present invention can prevent, by the plurality of slits 13, deterioration in the adhesion between the PAD 10 and the bonding wire even when the PAD 10 surface is shaved by the probing.

Referring to FIG. 6, on the PAD 10 surface after the probing, a probe mark 17 as a mark of the contact made by the probe 40 is formed. The probe mark 17 is present at a portion including the plurality of slits 13, and the shavings 16 is pushed in each of the slits 13 included in the probe mark 17. Then in a boding region 18, as a region of the PAD 10 to be joined with the bonding wire, only a small amount of shaving pile 15 is present on a part of an outer side, with little influence exerted on the adhesion between the PAD 10 and the bonding wire.

For the semiconductor device 1 of the present invention, the shape and the positions of the plurality of slits 13 provided at the PAD 10 are important, and in particular, a position and a direction when the probe 40 makes contact with the PAD 10 during the probing need to be considered. That is, only arranging the plurality of slits 13 at the PAD 10 raises a problem that the shavings produced as a result of the shifting of the probe 40 on the PAD surface during the probing cannot be reduced. For example, if no slit 13 is arranged in the inspection region 12 where the probe 40 shifts or if group of the aperture of the arranged slit 13 is small, the deterioration in the adhesion between the PAD 10 and the bonding wire cannot be prevented satisfactorily. A bonding pad 100 of Japanese Patent Application JP2003-243443A shown in FIG. 2 applies to this case. Referring to FIG. 2, the recess portion 101 is arranged on the bonding pad 100 but is not arranged in a region 111 where a probe shifts, which therefore results in failure to suppress production of shavings on a surface despite the presence of the recess portion 101. Therefore, a large shaving pile is produced in a bonding region, which possibly causes poor adhesion between the bonding pad 100 and a bonding wire.

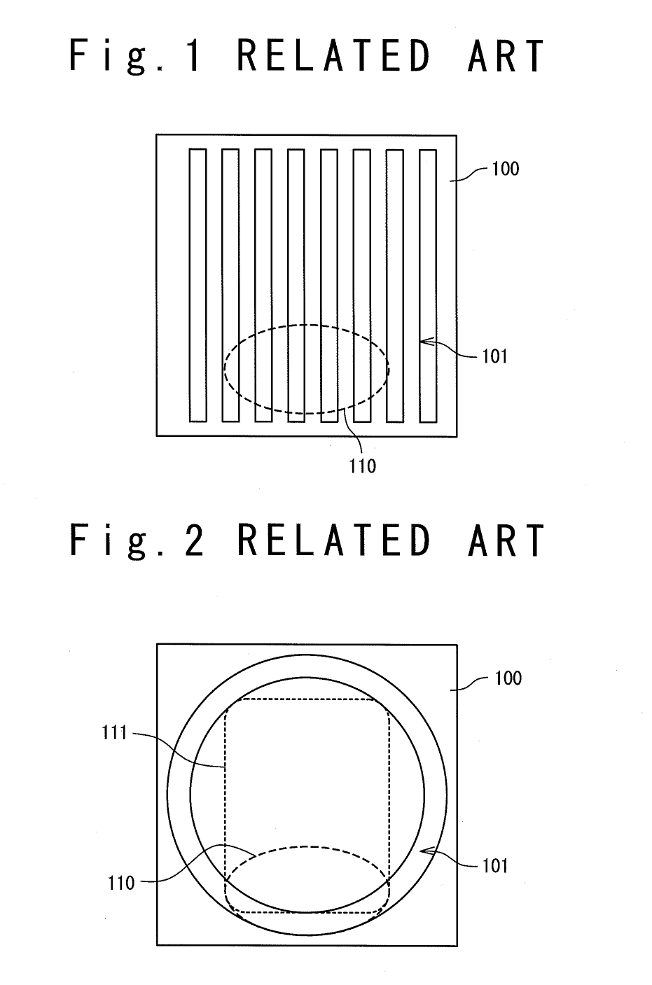

Moreover, arranging the plurality of slits 13 on the PAD 10 without considering the shape and size thereof results in a too large group of the aperture of the plurality of slits 13, which causes concern that the amount of the conductive material of the contact start region 11 with which the probe 40 makes first contact becomes small. The conductive material of the contact start region 11 serves as a cushion material that receives the impact added upon the contact made by the probe 40. Therefore, a decrease in the conductive material increases damage to a lower layer of the PAD 10, which may lead to breakage of the lower layer in a worst case. The bonding pad 100 of Japanese Patent Application JP2003-243443A shown in FIG. 1 applies to this case. That is, since a large number of recess portions 101 are arranged in the region 110 where the probe makes contact with the bonding pad 100, a conductive material of the region 110 decreases, with great damage to an lower layer of the bonding pad 100, which possibly results in breakage of the lower layer of the bonding pad 100 in a worst case.

In other words, the semiconductor device 1 of the present invention has the plurality of slits 13 arranged at the PAD 10 in view of these problems, thus providing advantages of preventing the poor adhesion with the bonding wire and also suppressing the damage to the lower layer.

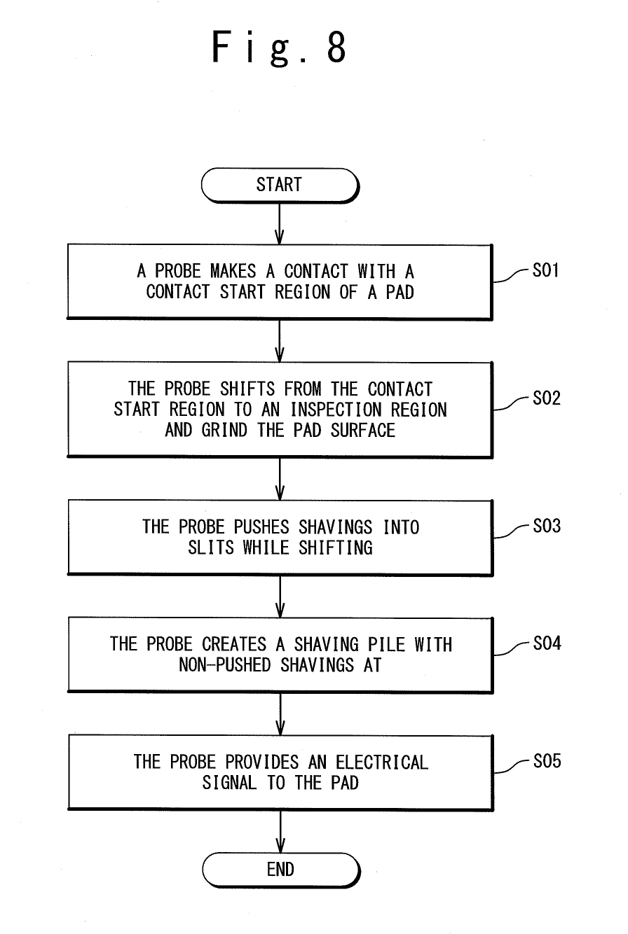

FIG. 8 is a flow chart showing a method of inspecting the electrical characteristic of the semiconductor device 1 of the first embodiment of the present invention with the probe card. Referring to FIG. 8, the method of inspecting the semiconductor device 1 according to the first embodiment of the present invention will be described.

The probe 40 of the probe card for inspecting the electrical characteristic of the semiconductor device 1 makes contact with the contact start region 11 of the PAD 10 (step S01).

Based on the force pressing the probe card, the probe 40 shifts from the contact start region 11 to the inspection region 12 to thereby grind the region 14 on the PAD 10 surface (step S02).

The probe 40 pushes the shavings, which have been produced by grinding the region 14 on the PAD 10 surface, into the slits 13 while shifting (step S03).

The probe 40 pushes almost all the shavings into the slits 13 or creates with the non-pushed shavings a shaving pile 15, smaller than a shaving pile formed when no slit 13 is provided, at an outer peripheral portion of the bonding region 18 (step S04).

The probe 40 provides to the PAD 10 an electrical signal provided from a measuring instrument (step S05).

As described above, since the semiconductor device 1 according to the first embodiment of the present invention has the PAD 10 with the plurality of slits 13 arranged in the direction in which the probe 40 shifts, the shavings remaining on the PAD 10 surface and the shaving pile 15 based on the shift of the probe 40 can be reduced, which consequently provide an advantage of improving a force of the adhesion between the PAD 10 and the bonding wire. Further, since the semiconductor device 1 of the present invention includes almost no slit 13 in the contact start region 11 of the PAD 10, the conductive material that absorbs the impact upon the contact made by the probe 40 is provided satisfactorily, thus providing an advantage of not causing the breakage of the lower layer.

### Second Embodiment

A second embodiment of the present invention will be described. The semiconductor device 1 according to the second embodiment of the present invention differs from that of the first embodiment in a shape of a slit section provided at a PAD 10. In this embodiment the slit section includes a plurality of slits 13. Components having a same configuration as those of the first embodiment are provided with the same numerals and thus omitted from the description.

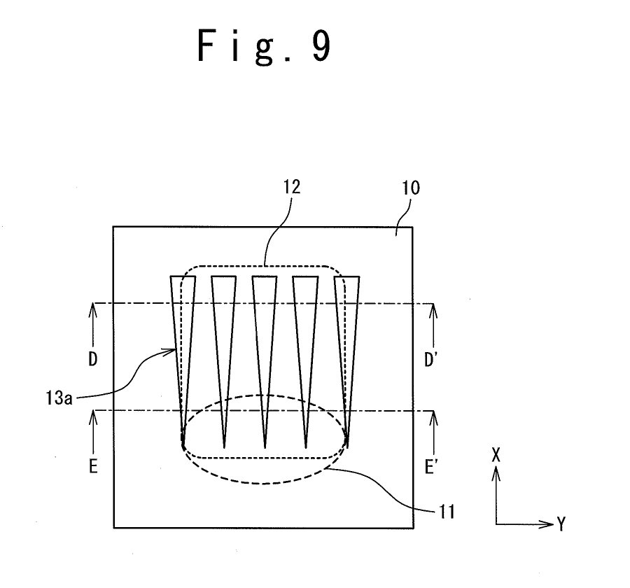

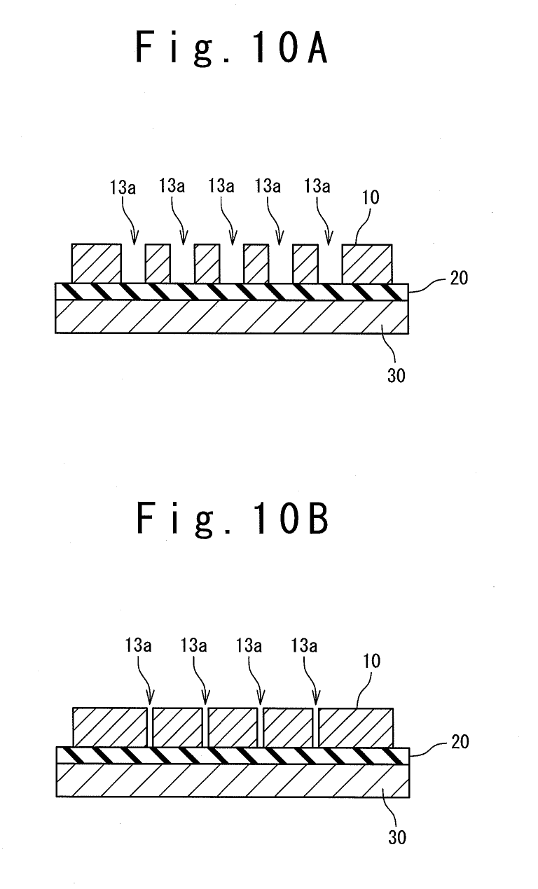

FIG. 9 is a plan view of the PAD 10 of the semiconductor device 1 according to the second embodiment of the present invention. FIG. 10A is a sectional view of the PAD 10 shown in FIG. 9, taken along line D-D′. FIG. 10B is a sectional view of the PAD 10 shown in FIG. 9, taken along line E-E′. FIGS. 9, 10A, and 10B show states before the inspection made with the probes of the probe card. Referring to FIGS. 9, 10A, and 10B, the PAD 10 includes a plurality of slits 13a.

Each of the plurality of slits 13a is a hole vertically penetrating a whole thickness of the PAD 10 from the higher surface to the lower surface in contact with an insulation film 20. Each of the plurality of slits 13a is, as is the case with that of the first embodiment, arranged on the PAD, in view of a position contacted by the probe and a direction in which the probe shifts. More specifically, the plurality of slits 13a are included in a contact start region 11 located outwardly of a center of the PAD 10 surface and an inspection region 12 so located as to include the center of the PAD 10 surface. Then group of aperture of the plurality of slits 13a included in the contact start region 11 is smaller than group of aperture of the plurality of slits 13a included in the inspection region 12.

The plurality of slits 13a of the second embodiment of the present invention are each shaped with the group of the aperture thereof increasing gradually from the contact start region 11 to the inspection region 12. Referring to FIG. 9, the shape of each of the slits 13a is a triangle with one vertex included in the contact start region 11 and with two vertexes included in the inspection region 12. In the contact start region 11, the group of the aperture of the slits 13a is small, and the group of the aperture of the slits 13a increase gradually with increasing distance from the contact start region 11. In this case, each slit 13a has, for example, a triangular shape with a 5-μm base and a height of 40 μm. Moreover, an interval between the slits 13 is preferably smaller than a thickness of the probe and is, for example, approximately 10 μm. Note that the shape of the plurality of slits 13a of the second embodiment of the present invention may be a circular shape including an oval or any other polygonal shape with the group of the aperture of the slit 13a increasing stepwise with distance from the contact start region 11. Further, in FIG. 9, each slit 13a is arranged as one hole penetrating from the contact start region 11 to the inspection region 12, but a plurality of penetrating holes may be aligned in an X direction and each shaped with group of an aperture thereof increasing gradually. Also in this case, each slit 13a may be circular-shaped or polygonal-shaped.

The semiconductor device 1 of the second embodiment of the present invention has the slits 13a whose aperture increases in a direction in which the probe shifts, thus making it easier for shavings on the PAD 10 surface to fill in the slits 13a, which improves an advantage of reducing a shaving pile. Further, with the semiconductor device 1 of the second embodiment of the present invention, as is the case with that of the first embodiment, the group of aperture of the slits 13a in the contact start region 11 with which the probe makes first contact is small and a sufficient conductive material that absorbs the impact upon the contact made by the probe is provided, which can therefore suppress damage to an lower layer.

As described above, the semiconductor device 1 of the present invention can reduce the shavings on the PAD 10 surface and the shaving pile produced by the shift of the probe to thereby improve the adhesion between the PAD 10 and the bonding wire and can also suppress the damage caused by the impact of the contact made by the probe during the probing. Note that the embodiments of the present invention can be combined within a consistent range.

What is claimed is:

1. A semiconductor device comprising:
an electrode pad; and
a lower layer arranged under said electrode pad,
wherein said electrode pad comprises:
a slit section including at least one slit which is formed to penetrate a whole thickness of said electrode pad from a higher surface to a lower surface in contact with said lower layer;
a contact start region, arranged in said higher surface, on which a probe makes a contact; and
an inspection region, arranged in said higher surface, on which said probe makes an inspection upon said semiconductor device,
wherein said slit section comprises:
a first group of aperture open to said inspection region; and
a second group of aperture open to said contact start region smaller than said first group of aperture.

2. The semiconductor device according to claim 1,
wherein said slit section comprises:
a plurality of slits,
wherein an interval between each of said plurality of slits is smaller than a thickness of said probe.

3. The semiconductor device according to claim 2,
wherein each of said plurality of slits comprises:
a polygonal shape.

4. The semiconductor device according to claim 2,
wherein each of said plurality of slits comprises:
a triangular shape with one vertex included in said contact start region and two vertexes included in said inspection region.

5. The semiconductor device according to claim 2,
wherein each of said plurality of slits comprises:
an oval shape.

6. A method of inspecting an electrical characteristic of a semiconductor device, comprising:
making a contact between a probe and contact start region arranged in a higher surface of an electrode pad;
shifting said probe from said contact start region to an inspection region of said electrode pad;
grinding with said probe a higher surface of said electrode pad;
pushing with said probe shavings produced while said grinding into a slit section of said electrode pad;
creating a shaving pile with shavings remaining on said higher surface of said electrode pad; and
providing an electrical signal to said electrode pad via said probe.
